(19) United States
(12) Patent Application Publication
(10) Pub. No.: US 2026/0327064 A1
(43) Pub. Date: Oct. 22, 2026

(54) SYNCHRONOUS DRIVE FOR MEMS

(71) Applicant: kiiz Technologies GmbH, Itzehoe (DE)

(72) Inventors: Leon POHL, Schwentinental (DE); Marco MEOLA, Dr., Kiel (DE); Wjatscheslaw GALJAN, Nüitzen (DE)

(21) Appl. No.: 19/480,953

(22) PCT Filed: Apr. 23, 2024
(86) PCT No.: PCT/EP2024/061010

§ 371 Date: Nov. 3, 2025

(30) Foreign Application Priority Data
May 2, 2023 (DE) 10 2023 111 340.2

(51) Int. Cl. B81B 7/00; H03K 5/00

(52) U.S. Cl. CPC B81B 7/008; H03K 5/00006; B81B 2207/03

(57) ABSTRACT

A drive device for a mechanical oscillation of a microelectromechanical system includes an electrical oscillator that is designed and configured such that it generates an electrical output signal with a first frequency. The electrical oscillator is designed and configured such that the first frequency of the output signal is adjustable to a target frequency. The drive device is designed and configured such that the electrical oscillator is configured to be connected at least indirectly to the microelectromechanical system in order to drive the mechanical oscillation of the microelectromechanical system with a drive signal. The drive device includes a control device. The control device is designed and configured in such a way that the control device receives an electrical feedback signal from the microelectromechanical system during operation with a microelectromechanical system.

The present application relates to a drive device for a mechanical oscillation of a microelectromechanical system (MEMS), a combination of a drive device according to one of the preceding claims with a mechanically oscillatable microelectromechanical system, a spectacle device comprising a drive device according to the invention or a combination according to the invention and a process for driving a microelectromechanical system, in particular a MEMS scanner.

MEMS to be driven resonantly, in particular MEMS scanners, and their drives must be designed to be particularly energy-efficient and miniaturised if they are to be integrated into spectacles, for example. The solutions known to date do not manage to fulfil both requirements to a satisfactory degree.

Against this background, it is a problem of the present invention to enable a particularly energy-efficient and miniaturised use of a MEMS, in particular a MEMS scanner. Against this background, it is particularly desirable to be able to dispense with electronic components that cannot be transferred to an integrated system.

According to the invention, this problem is solved by a drive device for a mechanical oscillation of a microelectromechanical system, wherein the drive device comprises an electrical oscillator, wherein the electrical oscillator is designed and configured such that it generates an electrical output signal with a first frequency f1, wherein the electrical oscillator is designed and configured such that the first frequency f1 of the output signal can be set to a target frequency f1_target, wherein the drive device is designed and configured such that the electrical oscillator can be connected at least indirectly to the microelectromechanical system in order to drive the mechanical oscillation of the microelectromechanical system with a drive signal, wherein the drive device has a control device, wherein the control device is designed and configured such that the control device receives an electrical feedback signal from the microelectromechanical system during operation with a microelectromechanical system, wherein the control device is designed and configured such that a controlled variable R, which is dependent on the feedback signal and/or on the drive signal (and in particular is dependent on the feedback signal and on the drive signal), can be set to a target value R_target, wherein the control device is designed and configured such that it calculates the controlled variable R in operation with a microelectromechanical system, wherein the control device is designed, configured and connected to the electrical oscillator such that it sets the target frequency f1_target, which can be set on the electrical oscillator, as a function of the measured controlled variable R in order to control the controlled variable R to the target value R_target.

The MEMS is a resonator with a high Q factor. The drive device according to the invention makes it possible in an advantageous way to utilise this property of the MEMS in order to effect elevations in the frequency stability of the exciting oscillator, for example a voltage-controlled electrical oscillator. This is because the feedback signal can be used with the aid of the control device to limit the oscillation of the exciting oscillator as far as possible to the natural frequency to be excited. This means that no further oscillator with a high Q factor or an oscillator with better frequency stability than that of typical RC oscillators is required. In particular, no crystal oscillator is required to increase the frequency stability. However, the excitation oscillator and the MEMS are also synchronised by the drive device according to the invention, so that the excitation oscillator drives the MEMS constantly at a certain natural frequency, even if the natural frequency changes due to thermal effects. The drive device according to the invention therefore tracks the natural frequency used when the MEMS is in use.

An electrical oscillator within the meaning of the present invention, which is designed and configured such that the first frequency f1 of the output signal can be adjusted to a target frequency f1_target, is in other words designed such that a user can vary the target frequency f1_target without having to structurally change the electrical oscillator itself. An example of such an oscillator is a voltage-controlled electrical oscillator (VCO for short).

According to one embodiment of the drive device according to the invention, the feedback signal reflects the deflection of the mechanical oscillation of the microelectromechanical system. In particular, the MEMS can be a piezoelectric MEMS, so that the feedback signal reflects the mechanical deflection of the piezoelectric element.

According to one embodiment of the drive device according to the invention, the control device and controlled variable R are designed in such a way that controlling the controlled variable R by the control device during operation with a microelectromechanical system to a target value R_target causes the phase shift P between the drive signal and the feedback signal, which leaves the microelectromechanical system directly and is therefore native, to be kept constant over time. This phase shift is decisive for whether the MEMS is driven resonantly or not.

Therefore, this embodiment makes it possible in an advantageous way to maintain the resonant driving of the MEMS even if there are external disturbances such as a thermally induced change in the natural frequency of the MEMS.

According to one embodiment of the drive device according to the invention, the amount of the phase shift P (the phase shift between the drive signal and the feedback signal leaving the microelectromechanical system directly and therefore native) to be kept constant in time is between 40 degrees and 140 degrees, preferably between 60 degrees and 120 degrees and particularly preferably between 70 degrees and 110 degrees.

According to one embodiment of the drive device according to the invention, the controlled variable R is the phase shift P of the drive signal and native feedback signal, so that the control device is designed and configured such that, in operation with a microelectromechanical system, it adjusts the electrical oscillator in order to control the phase shift P of the drive signal and native feedback signal to a target value for the phase shift P_target. The phase shift as a controlled variable directly ensures that resonant driving of the MEMS is guaranteed with the control and is therefore robust against changes to the system, such as those that can occur due to maintenance.

According to one embodiment of the drive device according to the invention, the controlled variable R is the quadrature Q of the feedback signal in relation to the drive signal as the reference signal, wherein the control device is preferably designed and configured such that controlling the quadrature Q to a target value for the quadrature of zero causes the phase shift of the drive signal and native feedback signal to be controlled to a predefined target value P_target. This greatly simplifies the calculations required to keep a certain phase shift constant. This in turn elevates the energy efficiency of the drive device.

According to one embodiment of the drive device according to the invention, the control device comprises a calculation unit, for example a phase detector and/or IQ demodulator (in particular an IQ demodulator), wherein the drive device is designed and configured such that, during operation with the microelectromechanical system, the calculation unit firstly receives the drive signal or a first clock signal T1 synchronised with the drive signal and secondly receives the feedback signal of the microelectromechanical system indirectly, e.g. in filtered form and/or amplified form and/or digitized, or directly, wherein the calculation unit is designed and configured such that, in operation with a microelectromechanical system, it calculates the controlled variable R, for example
the quadrature Q of the feedback signal, either discretely or continuously over time,
the phase shift between the drive signal and the native feedback signal,
   wherein the phase detector preferably comprises an IQ demodulator. This calculation enables the controlled variable R to be controlled in an advantageous manner.

In particular, the calculation unit can be designed in such a way that the calculations performed in the calculation unit are synchronised with the drive signal. This allows the calculations to be simplified and thus energy efficiency to be elevated.

According to one embodiment of the drive device according to the invention, the control device has a control unit, wherein the control unit and the calculation unit are designed and configured in such a way that the control unit receives the controlled variable calculated by the calculation unit during operation with the microelectromechanical system and calculates the difference D between the calculated controlled variable and the target value for the controlled variable R_target, wherein the control unit and the electrical oscillator are designed such that the control unit sets the target frequency f1_target of the electrical oscillator as a function of the calculated difference D, wherein the control unit preferably comprises a loop filter with a transfer function specified for the control of the electrical oscillator. In particular, the control unit may be a so-called PLL control unit, i.e. a unit for controlling a phase-locked loop.

According to one embodiment of the drive device according to the invention, the drive device is designed and configured in such a way that the control unit also receives the drive signal or a second clock signal T2 synchronised with the drive signal during operation with the microelectromechanical system, so that the calculations performed in the control unit are performed synchronously with the drive signal. This makes it possible to simplify the calculations on the control unit and thus to elevate the energy efficiency of the drive device.

According to one embodiment of the drive device according to the invention, the drive device comprises a first clock generator, wherein the first clock generator is designed, configured, coupled to the electrical oscillator and connectable to the microelectromechanical system in such a way that the first clock generator receives the output signal of the electrical oscillator and converts it into the drive signal with a second frequency f2, wherein the first frequency f1 is an integer multiple, for example 1024 times or 512 times, of the second frequency f2, wherein the first clock generator is preferably a frequency divider or comprises such a frequency divider.

According to one embodiment of the drive device according to the invention, the drive device comprises a second clock generator, wherein the second clock generator is designed, configured and coupled to the electrical oscillator in such a way that the second clock generator receives the output signal of the electrical oscillator and converts it into the first clock signal T1 with a third frequency f3, wherein the first frequency f1 is an integer multiple of the third frequency f3, wherein the second clock generator is preferably a frequency divider or comprises such a frequency divider. This enables synchronisation between the drive signal and calculations on the calculation unit.

According to one embodiment of the drive device according to the invention, the drive device comprises a third clock generator, wherein the third clock generator is designed, configured and coupled to the electrical oscillator in such a way that the third clock generator receives the output signal of the electrical oscillator and converts it into the second clock signal T2 with a fourth frequency f4, wherein the first frequency f1 is an integer multiple of the fourth frequency f4, wherein the third clock generator is preferably a frequency divider or comprises such a frequency divider. This enables synchronisation between the drive signal and calculations on the control unit.

According to one embodiment of the drive device according to the invention, the control device has a sampling unit, wherein the drive device is designed and configured such that the sampling unit, in operation with the microelectromechanical system, receives the drive signal or a third clock signal T3 synchronised with the drive signal on the one hand and, on the other hand, receives the feedback signal of the microelectromechanical system indirectly, e.g. in filtered and/or amplified form, or directly, wherein the sampling unit is designed and configured such that it samples the received feedback signal in discrete time at a sampling frequency, for example with 32 samples per oscillation period of the drive signal, so that the sampling unit provides the digitised feedback signal as an output signal, wherein the sampling frequency is in particular the first frequency f1 of the drive signal, a fifth frequency f5 of the third clock signal T3 or a reduced or elevated frequency f5′ compared to the fifth frequency f5, wherein the latter frequency f5′ can result from an integral formation over a fixed number of data points of the feedback signal to be digitised measured at the fifth frequency, wherein the control device is preferably designed such that the sampling unit is connected upstream of a calculation unit as described above, so that the feedback signal is present in discrete time at the input of the calculation unit.

The sampling unit can be designed as an analogue-to-digital converter or comprise such a converter.

According to one embodiment of the drive device according to the invention, the drive device comprises a fourth clock generator, wherein the fourth clock generator is designed, configured and coupled to the electrical oscillator in such a way that the fourth clock generator receives the output signal of the electrical oscillator and converts it into the third clock signal T3 with the fifth frequency f5, wherein the first frequency f1 is an integer multiple of the fifth frequency f5, wherein the fourth clock generator is preferably a frequency divider or comprises such a frequency divider. This enables simplified calculations in the calculation unit and thus enables an increase in energy efficiency.

According to one embodiment of the drive device according to the invention, the control device has a low-pass filter, which is preferably designed as a switched-capacitor filter, wherein the low-pass filter is designed and configured according to a first alternative such that, in operation with the microelectromechanical system, the low-pass filter exclusively receives and filters the feedback signal of the microelectromechanical system directly or indirectly (e.g. in a filtered and/or amplified form). According to a second alternative, the low-pass filter is designed and configured such that, in operation with the microelectromechanical system, the low-pass filter receives the feedback signal of the microelectromechanical system directly or indirectly (e.g. in a filtered and/or amplified form) and also receives the drive signal or a fourth clock signal T4 synchronised with the drive signal and filters it in a discrete-time manner, in particular at the rate of the first frequency f1 of the drive signal or at the rate of the sixth frequency f6 of the fourth clock signal T4. The control device is preferably designed in such a way that the low-pass filter is connected upstream of a sampling unit as described above, so that the feedback signal is low-pass filtered at the input of the sampling unit.

The design of the low-pass filter as a switched-capacitor filter enables the drive device to be designed in such a way that a possible change in the phase of the feedback signal by the low-pass filter is independent of a change in the natural frequency of the MEMS. A phase accuracy of the low-pass filter or a phase shift caused by the low-pass filter therefore remains unaffected or unchanged by a change in the natural frequency of the MEMS.

According to one embodiment of the drive device according to the invention, the low-pass filter is designed according to the second alternative, wherein the drive device comprises a fifth clock generator, wherein the fifth clock generator is designed, configured and coupled to the electrical oscillator in such a way that the fifth clock generator receives the output signal of the electrical oscillator and converts it into the fifth clock signal T4 with the sixth frequency f6, wherein the first frequency f1 is an integer multiple of the sixth frequency f6, wherein the fifth clock generator is preferably a frequency divider or comprises such a frequency divider.

According to one embodiment of the drive device according to the invention, the drive device comprises a first signal amplifier, wherein the first signal amplifier is designed, configured and arranged such that, in operation with the microelectromechanical system, it amplifies the drive signal and is connected upstream of the microelectromechanical system, so that the drive signal amplified by means of the first signal amplifier is present at the input of the microelectromechanical system.

According to one embodiment of the drive device according to the invention, the drive device comprises a second signal amplifier, wherein the second signal amplifier is designed, configured and arranged in such a way that it amplifies the feedback signal during operation with the microelectromechanical system and is connected upstream of the control device, so that the feedback signal amplified by means of the second signal amplifier is present at the input of the control device.

According to one embodiment of the drive device according to the invention, the control device comprises a calculation unit designed at least as an IQ demodulator according to the above description and a sampling unit according to the above description, wherein the calculation unit is configured such that it accesses a lookup table stored in the control device for calculating the controlled variable R. This is a particularly strong simplification of a calculation and therefore particularly energy-efficient.

According to one embodiment of the drive device according to the invention, the drive device comprises the second clock generator and the fourth clock generator and is designed such that the calculation unit and the sampling unit are operated with clock signals T1 and T3 which are synchronised with the drive signal, wherein a precalculated value X(i) of at least one trigonometric function TRI, for example a sine or a cosine function, is assigned to each period i of the clock signal T1 or each period i of the clock signal T3 in the lookup table. Since the calculation of trigonometric functions requires high computing capacities, a particularly large amount of energy can be saved during the calculations.

According to one embodiment of the drive device according to the invention, the electrical oscillator is a voltage-controlled electrical oscillator.

According to one embodiment of the drive device according to the invention, the drive device is at least partially and preferably completely designed as an integrated electronic circuit.

According to one embodiment of the drive device according to the invention, the control device has a bandpass filter, wherein the bandpass filter receives the feedback signal, filters it and makes the filtered feedback signal available, wherein the drive device preferably comprises a calculation unit designed as a phase detector (as described above) and the bandpass filter is located upstream of the phase detector, so that the phase detector receives the bandpass-filtered feedback signal.

The problem underlying the invention is also solved by a combination of a drive device according to one of the embodiments described above with a mechanically oscillatable microelectromechanical system (MEMS).

According to one embodiment of the combination according to the invention, the drive device is designed and configured such that the electrical oscillator is at least indirectly connected to the microelectromechanical system in order to drive the mechanical oscillation of the microelectromechanical system with the drive signal, wherein the mechanical oscillation of the microelectromechanical system generates the feedback signal, wherein the controlled variable R is preferably designed in such a way that the regulation of the controlled variable R to the target value R_target causes a resonant driving of the oscillation of the microelectromechanical system, wherein the microelectromechanical system can in particular be a piezoelectric-microelectromechanical system and/or a microoptoelectromechanical system. The MEMS thereby elevates the frequency stability of the electrical oscillator.

According to one embodiment of the combination according to the invention, the microelectromechanical system is a MEMS scanner, preferably a resonantly drivable MEMS scanner.

The problem underlying the invention is also solved by a eyewear device comprising a drive device according to one of the embodiments described above and/or a combination according to one of the embodiments described above.

According to one embodiment of the eyewear device according to the invention, the eyewear device comprises an imaging device for projecting images into the field of view of the user of the eyewear device, wherein the eyewear device preferably does not comprise a quartz oscillator.

The problem underlying the invention is also solved by a process for driving a microelectromechanical system, in particular a MEMS scanner, comprising the following steps:
a) providing a drive signal and driving a mechanical oscillation of the microelectromechanical system with the drive signal,
b) measuring feedback signal of the mechanical oscillation of the microelectromechanical system,
c) setting a target value P_target for the phase shift P between the drive signal and the native feedback signal,
d) setting a target variable R_target for a controlled variable R which is dependent on the drive signal and/or the feedback signal, wherein the target variable R_target of the controlled variable is selected such that the target variable P_target for the phase shift P is also reached when it is reached,
e) determining the controlled variable R,
f) determining the difference D between the controlled variable R and the target value R_target of the controlled variable,
g) modifying the drive signal for step a), in particular modifying the frequency of the drive signal as a function of the difference D determined in step f) in order to minimise the difference D.

Preferably, the controlled variable is dependent on both the drive signal and the feedback signal.

According to one embodiment of the process according to the invention, steps e), f) and g) are continuously repeated in the form of a control loop.

According to one embodiment of the process according to the invention, the modification in step g) is carried out according to a predefined transfer function which is dependent on the difference D.

According to one embodiment of the process according to the invention, the controlled variable R is determined in step e) periodically and synchronously with the driving of the mechanical oscillation of the microelectromechanical system with the drive signal.

According to one embodiment of the process according to the invention, the controlled variable R is the phase shift P itself or the quadrature Q of the feedback signal in relation to a clock signal designed to be synchronous with the drive signal and serving as a reference signal.

Enumerations and numbering such as second clock generator do not imply a number, but only serve to clearly identify the elements described. If, for example, a second clock generator is mentioned, this is to be understood as a name and does not necessarily mean that two clock generators must be present.

Where reference is made to a signal such as the feedback signal, this description refers to the native signal as well as to any form of the signal that has been further developed by filtering or amplification or similar loading. Where reference is made to the native signal—in other words, the original signal—the term native signal is used explicitly.

The features of the embodiments described above can be combined with each other, unless expressly excluded.

Further advantages, features and embodiments can be seen from the figure shown and its description.

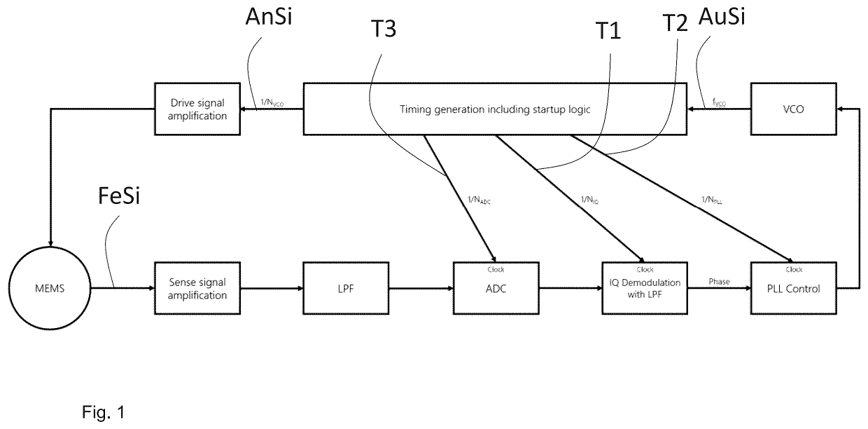

FIG. 1 shows a schematic circuit diagram of an embodiment of a combination of a MEMS, in particular a MEMS scanner, according to the invention (therefore referred to here as MEMS and hereinafter also referred to as MEMS scanner) with a drive device.

FIG. 1 shows a schematic circuit diagram with an electrical oscillator in the sense of the present invention in the form of a trimmable oscillator (referred to here as VCO), which provides an output signal AuSi with a frequency f_{VCO} (f1). Downstream there is a timing block for generating all the clock signals required in the system for the discrete-time circuits on the basis of a common reference clock (referred to here as ‘clock generation including start logic’). In this example, clock signals are provided for the analogue-to-digital converter (ADC for short) the clock signal T3 with the frequency f_{ADC} (corresponds to the frequency f5 described above); the IQ demodulator with low-pass filter (referred to here as ‘IQ demodulation with LPF’) the clock signal T1 with the frequency f_{IQ} (corresponds to the frequency f3 described above); the PLL controller the clock signal T2 with the frequency f_{PLL} (corresponds to the frequency f4 described above); and of course the MEMS scanner the drive signal AnSi with the frequency f_{MEMS} (corresponds to the frequency f2 described above). However, it is conceivable that, for example, the low-pass filter (LPF) is also executed in discrete time before the ADC and is therefore also supplied with a clock.

The clock signals are designed in such a way that all clock signals are linked to the frequency of the drive signal via a respective natural number N. All discrete-time circuits therefore run in synchronisation with the MEMS.

The drive signal generated by the timing block is then amplified in a downstream block (referred to here as ‘amplifier for drive signal’). This is necessary in order to supply the MEMS scanner with a drive signal of suitable amplitude for the desired operating point. The amplified drive signal with frequency f_{MEMS} is then used to excite the MEMS scanner.

If the frequency is selected correctly, the MEMS scanner then begins to oscillate mechanically. The high quality of the MEMS now helps to filter the drive signal AnSi. This means that the oscillation frequency of the MEMS corresponds to the average frequency of the drive signal AnSi, but with lower temporal jitter, i.e. improved frequency stability (similar to a discrete quartz oscillator).

The feedback signal FeSi generated by the MEMS scanner, also known as the sense signal, represents the current deflection angle of the mirror plate integrated in the MEMS scanner and therefore corresponds directly to the current phase position of the MEMS in relation to its drive signal AnSi.

For further signal processing, the feedback signal FeSi is first amplified continuously over time (referred to here as ‘amplifier for feedback signal’), which can be done using a charge amplifier or a transimpedance amplifier, for example. This is necessary so that the feedback signal FeSi can be electrically loaded by the following blocks.

The amplified feedback signal FeSi is now filtered by an anti-aliasing low-pass filter (LPF) and then digitised using an analogue-to-digital converter (ADC). The low-pass filter can be continuous-time or discrete-time. In the latter case, however, the low-pass filter must be supplied with a suitable clock, which can also be generated by the timing block described above. The advantage of a discrete-time filter is a more stable phase response. However, this advantage must be individually weighed against the disadvantage of a possible increased noise level.

At this point, it should be emphasized that the ADC in this embodiment represents the transition between the analogue and digital environment. In principle, however, a completely analogue implementation of the synchronous drive device shown is also conceivable, for which no ADC is then required.

After the feedback signal FeSi has been sampled by the ADC synchronously with the movement of the MEMS, a time-discrete and synchronised IQ demodulation with integrated low-pass filtering takes place. The instantaneous phase (and amplitude) of the largely sinusoidal feedback signal FeSi is extracted in relation to the excitation frequency of the MEMS, the frequency f_{MEMS} (f2), which serves as the input variable for the subsequent phase control. The integrated low-pass filter helps to filter out the unwanted frequency components that arise during demodulation.

Due to the fact that the sampling of the feedback signal is synchronised and thus always takes place at well-defined points in time, the mathematical calculations performed during signal processing can be massively simplified, thus also reducing the power consumption of the signal processing.

In order to close the phase-locked loop shown in FIG. 1, the phase shift P of the MEMS scanner (i.e. the native feedback signal) with respect to the drive signal AnSi known from the demodulation is passed to the block for controlling the phase-locked loop (‘PLL control’). In this block, the measured phase shift P is compared with the desired target phase shift P_target. Alternatively, an equivalent controlled variable can also be compared here with its target value if the effect is the same, namely the control of the phase shift P for resonant driving of the MEMS.

The problem of the PLL control unit is to minimise the calculated phase error, the difference D. For this purpose, the input variable f_target of the VCO and therefore also the frequency f1 of the output signal AuSi is varied depending on the current phase error.

If the frequency of the VCO's output signal AuSi is too high for a short time due to the typically sub-optimal frequency stability of a VCO, for example, the MEMS scanner cannot follow these spontaneous frequency changes immediately and therefore continues to oscillate at a constant frequency. This leads to a measurable phase error, which in turn causes the control of the phase-locked loop—the PLL control—to reduce the target frequency of the VCO (i.e. f1_target in the context of this invention). In this way, the MEMS acts as a stabilising element of the entire synchronous drive concept and thus improves the frequency stability of the integrated oscillator (e.g. VCO) without the need to use a discrete (quartz) oscillator with higher power consumption and larger installation space.

The flow chart described above is repeated periodically so that a largely defined phase shift P between the drive signal AnSi and the native feedback signal FeSi of the MEMS scanner occurs.

If it is now assumed that the resonant frequency of the MEMS scanner changes over time, for example due to external temperature fluctuations, this would also lead to a measurable phase error (a difference D in the sense of the present invention), which is compensated for by the control loop. In this way, the entire system always remains synchronised.

1. A drive device for a mechanical oscillation of a microelectromechanical system, wherein the drive device comprises an electrical oscillator,
wherein the electrical oscillator is designed and configured such that it generates an electrical output signal (AuSi) with a first frequency (f1),
wherein the electrical oscillator is designed and configured such that the first frequency (f1) of the output signal (AuSi) is adjustable to a target frequency (f1_target),
wherein the drive device is designed and configured such that the electrical oscillator can be connected at least indirectly to the microelectromechanical system in order to drive the mechanical oscillation of the microelectromechanical system with a drive signal (AnSi), wherein the drive device comprises a control device,
wherein the control device is designed and configured in such a way that the control device receives an electrical feedback signal (FeSi) from the microelectromechanical system during operation with a microelectromechanical system,
wherein the control device is designed and configured such that a controlled variable (R), which is dependent on the feedback signal (FeSi) and/or on the drive signal (AnSi), can be set to a target value (R_target),
wherein the control device is designed and configured in such a way that it calculates the controlled variable (R) during operation with a microelectromechanical system,
wherein the control device is designed, configured and connected to the electrical oscillator in such a way that it adjusts the target frequency (f1_target), which can be set on the electrical oscillator, as a function of the measured controlled variable (R) in order to control the controlled variable (R) to the target value (R_target).

2. The drive device according to claim 1,
wherein the feedback signal reflects the deflection of the mechanical oscillation of the microelectromechanical system.

3. The drive device according to claim 1,
wherein the control device and controlled variable (R) are designed such that a regulation of the controlled variable (R) by the control device in operation with a microelectromechanical system to a target value (R_target) causes the phase shift between the drive signal (AnSi) and the feedback signal (FeSi), which leaves the microelectromechanical system and is therefore native, to be kept constant over time.

4. The drive device according to claim 3,
wherein the amount of the time-constant phase shift P is between 40 degrees and 140 degrees, preferably between 60 degrees and 120 degrees and particularly preferably between 70 degrees and 110 degrees.

5. The drive device according to claim 1,
wherein the controlled variable is the phase shift (P) of drive signal (AnSi) and native feedback signal (FeSi), so that the control device is designed and configured such that, in operation with a microelectromechanical system, it adjusts the electrical oscillator in order to control the phase shift (P) of drive signal (AnSi) and native feedback signal FeSi to a target value for the phase shift (P_target).

6. The drive device according to claim 1,
wherein the controlled variable (R) is the quadrature (Q) of the feedback signal (FeSi) with respect to the drive signal (AnSi) as reference signal, wherein the control device is preferably designed and configured such that a control of the quadrature to a target value for the quadrature of zero causes a control of the phase shift of drive signal (AnSi) and native feedback signal (FeSi) to a predefined target value (P_target).

7. The drive device according to claim 1,
wherein the control device comprises a calculation unit, for example a phase detector and/or IQ demodulator,
wherein the drive device is designed and configured such that the calculation unit, in operation with the microelectromechanical system, on the one hand receives the drive signal (AnSi) or a first clock signal (T1) synchronised with the drive signal (AnSi) and on the other hand receives the feedback signal (FeSi) of the microelectromechanical system indirectly, e.g. in filtered and/or amplified form and/or digitised, or directly,
wherein the calculation unit is designed and configured in such a way that, in operation with a microelectromechanical system, it calculates the controlled variable R, for example
the quadrature Q of the feedback signal (FeSi) in relation to the drive signal as a reference signal and/or
the phase shift between the drive signal (AnSi) and the native feedback signal (FeSi),
wherein the phase detector preferably comprises an IQ demodulator.

8. The drive device according to claim 7, wherein the control device comprises a control unit,
wherein the control unit and the calculation unit are designed and configured such that, in operation with the microelectromechanical system, the control unit receives the controlled variable calculated by the calculation unit and calculates the difference (D) between the calculated controlled variable and the target value for the controlled variable (R_target),
wherein the control unit and the electrical oscillator are designed in such a way that the control unit adjusts the target frequency (f1_target) of the electrical oscillator as a function of the calculated difference (D),
wherein the control unit preferably comprises a loop filter with a transfer function specified for the control of the electrical oscillator.

9. The drive device according to claim 8,
wherein the drive device is designed and configured such that the control unit also receives the drive signal (AnSi) or a second clock signal (T2) synchronised with the drive signal (AnSi) during operation with the microelectromechanical system, so that the calculations performed in the control unit are performed synchronously with the drive signal (AnSi).

10. The drive device according to claim 1, wherein the drive device comprises a first clock generator,
wherein the first clock generator is designed, configured, coupled to the electrical oscillator and connectable to the microelectromechanical system such that the first clock generator receives the output signal (AuSi) of the electrical oscillator and converts it into the drive signal (AnSi) with a second frequency (f2), wherein the first frequency (f1) is an integer multiple, for example 1024 times or 512 times, of the second frequency (f2),
wherein the first clock generator is preferably a frequency divider or comprises such a frequency divider.

11. The drive device according to claim 7, wherein the drive device comprises a second clock generator,
wherein the second clock generator is designed, configured and coupled to the electrical oscillator such that the second clock generator receives the output signal (AuSi) of the electrical oscillator and converts it into the first clock signal (T1) with a third frequency (f3), wherein the first frequency (f1) is an integer multiple of the third frequency (f3),
wherein the second clock generator is preferably a frequency divider or comprises such a frequency divider.

12. The drive device according to claim 9, the drive device comprises a third clock generator,
wherein the third clock generator is designed, configured and coupled to the electrical oscillator such that the third clock generator receives the output signal (AuSi) of the electrical oscillator and converts it into the second clock signal (T2) with a fourth frequency (f4), wherein the first frequency (f1) is an integer multiple of the fourth frequency (f4),
wherein the third clock generator is preferably a frequency divider or comprises such a frequency divider.

13. The drive device according to claim 7, wherein the control device comprises a sampling unit,
wherein the drive device is designed and configured such that the sampling unit, in operation with the microelectromechanical system, on the one hand receives the drive signal (AnSi) or a third clock signal (T3) synchronised with the drive signal (AnSi) and on the other hand receives the feedback signal (FeSi) of the microelectromechanical system indirectly, e.g. in filtered and/or amplified form, or directly,
wherein the sampling unit is designed and configured such that it samples the received feedback signal (FeSi) discretely in time with a sampling frequency, for example with 32 samples per oscillation period of the drive signal, so that the sampling unit provides the digitised feedback signal (FeSi) as an output signal,
wherein the sampling frequency may in particular be the first frequency (f1) of the drive signal (AnSi), a fifth frequency (f5) of the third clock signal (T3) or a frequency (f5′) which is reduced or elevated with respect to the fifth frequency (f5), wherein the latter frequency (f5′) may result from an integral formation over a fixed number of data points, measured at the fifth frequency, of the feedback signal to be digitised,
wherein the control device is preferably designed such that the sampling unit is connected upstream of a calculation unit, in particular the calculation unit, so that the feedback signal is present in discrete time at the input of the calculation unit,
wherein the sampling unit is particularly preferably designed as an analogue-to-digital converter or comprises such a converter.

14. The drive device according to claim 13, wherein the drive device comprises a fourth clock generator,
wherein the fourth clock generator is designed, configured and coupled to the electrical oscillator in such a way that the fourth clock generator receives the output signal (AuSi) of the electrical oscillator and converts it into the third clock signal (T3) with the fifth frequency (f5), wherein the first frequency (f1) is an integer multiple of the fifth frequency (f5),
wherein the fourth clock generator is preferably a frequency divider or comprises such a frequency divider.

15. The drive device according to claim 13,
wherein the control device comprises a low-pass filter, preferably designed as a switched-capacitor filter,
wherein the low-pass filter according to a first alternative is designed and configured such that the low-pass filter in operation with the microelectromechanical system exclusively receives and filters the feedback signal (FeSi) of the microelectromechanical system indirectly, e.g. in filtered and/or amplified form, or directly
or wherein the low-pass filter according to a second alternative is designed and configured in such a way that the low-pass filter in operation with the microelectromechanical system on the one hand receives the feedback signal (FeSi) of the microelectromechanical system indirectly, e.g. in filtered and/or amplified form, or directly and, on the other hand, receives the drive signal (AnSi) or a fourth clock signal (T4) synchronised with the drive signal (AnSi) and filters it discretely in time, in particular in time with the first frequency (f1) of the drive signal (AnSi) or in time with the sixth frequency (f6) of the fourth clock signal (T4),
wherein the control device is preferably designed such that the low-pass filter is connected upstream of a sampling unit, in particular the sampling unit, so that the feedback signal is low-pass filtered at the input of the sampling unit.

16. The drive device according to claim 15,
wherein the low-pass filter is designed according to the second alternative,
wherein the drive device comprises a fifth clock generator,
wherein the fifth clock generator is designed, configured and coupled to the electrical oscillator in such a way that the fifth clock generator receives the output signal (AuSi) of the electrical oscillator and converts it into the fifth clock signal (T4) with the sixth frequency (f6), wherein the first frequency (f1) is an integer multiple of the sixth frequency (f6),
wherein the fifth clock generator is preferably a frequency divider or comprises such a frequency divider.

17. The drive device according to claim 1, wherein the drive device comprises a first signal amplifier,
wherein the first signal amplifier is designed, configured and arranged such that, in operation with the microelectromechanical system, it amplifies the drive signal (AnSi) and is connected upstream of the microelectromechanical system, so that the drive signal (AnSi) amplified by means of the first signal amplifier is present at the input of the microelectromechanical system.

18-20. (canceled)

21. The drive device according to claim 1, wherein the electrical oscillator is a voltage controlled electrical oscillator.

22-27. (canceled)

28. A process for driving a microelectromechanical system, in particular a MEMS scanner, comprising:
a) Providing a drive signal (AnSi) and driving a mechanical oscillation of the microelectromechanical system with the drive signal,
b) measuring a feedback signal (FeSi) of the mechanical oscillation of the microelectromechanical system,
c) setting a target value (P_target) for the phase shift (P) between the drive signal (AnSi) and the native feedback signal (FeSi),
d) setting a target variable (R_target) for a controlled variable (R) which is dependent on the drive signal (AnSi) and/or the feedback signal (FeSi), wherein the target variable (R_target) of the controlled variable is selected in such a way that the target variable (P_target) for the phase shift (P) is also reached when it is reached,
e) Determining the controlled variable (R),
f) Determining the difference (D) between the controlled variable (R) and the target value (R_target) of the controlled variable,
g) modifying the drive signal (AnSi) for step a), in particular modifying the frequency of the drive signal (AnSi) as a function of the difference (D) determined in step f), in order to minimise the difference (D).

29-30. (canceled)

31. The process according to claim 28,
wherein the determining of the controlled variable in step e) is performed periodically and synchronously to driving the mechanical oscillation of the microelectromechanical system with the drive signal.

32. (canceled)
